(19) United States
(12) Patent Application Publication
(10) Pub. No.: US 2010/0213069 A1
(43) Pub. Date: Aug. 26, 2010

(54) MASTER PLATE AND METHOD OF MANUFACTURING THE SAME

(75) Inventors: Yoshiyuki KAMATA, Tokyo (JP); Takuya SHIMADA, Kawasaki-shi (JP); Masatoshi SAKURAI, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/712,045

(22) Filed: Feb. 24, 2010

(30) Foreign Application Priority Data
Feb. 26, 2009 (JP) 2009-044001

(51) Int. Cl. B23P 15/00; B32B 3/30; G11B 5/84; G03F 7/20

(52) U.S. Cl. 205/68; 428/172; 430/296

(57) ABSTRACT

According to one embodiment, a master plate for producing a stamper includes a substrate, and patterns of protrusions and recesses formed on the substrate and corresponding to patterns of recording tracks or recording bits in data areas and to information in servo areas, in which the protrusion has a structure in which a first metal layer, a silicon layer and a second metal layer are stacked on the substrate and a metal oxide film is formed on a surface of the protrusion.

### CROSS-REFERENCE TO RELATED APPLICATIONS

This application is based upon and claims the benefit of priority from Japanese Patent Application No. 2009-044001, filed Feb. 26, 2009, the entire contents of which are incorporated herein by reference.

### BACKGROUND

1. Field

One embodiment of the present invention relates to a master plate and to a method of manufacturing such a master plate.

2. Description of the Related Art

In recent years, in magnetic recording media installed in hard disk drives (HDDs), there is an increasing problem of disturbance of enhancement of track density due to interference between adjacent tracks. In particular, a serious technical subject is reduction in fringing of a magnetic field from a write head.

To solve such a problem, a discrete track recording medium (DTR medium) has been developed in which recording tracks are physically separated from each other. Since the DTR medium can reduce a side-erase phenomenon in writing and a side-read phenomenon in reading, making it possible to increase the track density. Therefore, the DTR medium is expected as a high-density magnetic recording medium.

Also, a bit patterned medium (BPM) in which a single magnetic dot is used as a single recording cell for read and write has been developed as a high-density magnetic recording medium which can suppress the thermal fluctuation phenomenon and medium noise.

Manufacturing of individual DTR medium or BPM by electron beam (EB) lithography results in significant increase in a production cost. In order to reduce the production cost, it is effective to use a method comprising producing a nickel stamper from a master plate with fine patterns formed by electron beam (EB) lithography, producing a large number of resin stampers from the Ni stamper by injection molding, and producing DTR media or BPM by UV (ultraviolet curing) imprinting using each resin stamper. This method enables to produce a large number of DTR media or BPM at a low cost.

Jpn. Pat. Appln. KOKAI Publication No. 2008-251095 discloses the following method of producing a master plate for a Ni stamper and producing a Ni stamper from the master plate. First, an EB resist is applied to the surface of a Si substrate and patterns are formed on the EB resist by EB lithography. The Si substrate is etched using the EB resist patterns as masks to form recesses. After the EB resist patterns are removed, the substrate is subjected to oxidation treatment to form a thermal oxide film on the surface of the patterns of protrusions and recesses of the Si substrate. A conductive film is formed on the thermal oxide film, a Ni electroforming layer is formed thereon, and the Ni electroforming layer is then peeled off to thereby form a Ni stamper.

If such a method of etching a Si substrate is used as mentioned above, such a phenomenon occurs that the recesses have different depths depending on densities of the patterns. This is because a microloading phenomenon cannot be neglected in reactive ion etching (RIE) for the Si substrate. When the patterns have uneven densities, reactive ions are selectively concentrated in regions having dense patterns where etching rate is increased, causing the microloading phenomenon. It is known that the microloading phenomenon markedly occurs when the recording track pitch is 100 nm or less.

If such a Ni stamper with recesses having uneven depths is set to an injection molding machine to form a resin stamper, the resin stamper has dispersion in the heights of the protrusions between servo areas and data areas.

Here, a method of producing a patterned medium (including DTR medium and BPM) by ultraviolet (UV) imprinting using a resin stamper will be described. First, a magnetic recording layer is deposited on a medium substrate and a UV-curable resist is applied to the surface of the magnetic recording layer. The resin stamper is pressed against the UV-curable resist to transfer patterns of protrusions and recesses. The UV-curable resist is irradiated with ultraviolet rays through the resin stamper to cure the UV-curable resist and then, the resin stamper is removed. The resist residues left on the bottoms of the recesses of the UV-curable resist. The magnetic recording layer is etched using the UV-curable resist patterns as masks to produce a patterned medium.

However, when the resin stamper with protrusions having uneven heights is used to produce the patterned medium, this poses a problem. This problem is caused by uneven thicknesses of the resist residues left in the recesses of the UV-curable resist resulting from the process that the resin stamper with protrusions having uneven heights is pressed against the UV-curable resist.

In the case of a resin stamper in which the protrusions in the data areas are relatively high and the protrusions in the servo areas are relatively low, for example, the resist residues in the servo areas are thick and therefore, the resist residues in the serve areas cannot be sufficiently removed. Consequently, this gives rise to poor transfer of the servo patterns to the patterned medium. A HDD in which the particular patterned medium is installed fails to perform servo tracking.

When the conditions for removal of the imprint residues are adjusted so as to remove the thick resist residues in the serve areas to avoid such a problem, excess etching is carried out in the data areas, leading to excessive side etching, so that the width of the recording tracks is narrowed. In the worst case, the recording tracks cannot be formed resultantly.

Also, Jpn. Pat. Appln. KOKAI Publication No. 2008-251095 discloses another method to manufacture a stamper described below. First, a thermal oxide film is formed on the surface of a Si substrate, an EB resist is applied to the thermal oxide film, and patterns are formed on the EB resist by EB lithography. The thermal oxide film is etched using the EB resist patterns as masks to form recesses. After the EB resist patterns are removed, a conductive film is deposited on the patterns of protrusions and recesses of the thermal oxide film. A Ni electroforming layer is formed thereon and then, the Ni electroforming layer is peeled off to manufacture a Ni stamper. Because the Si substrate is not etched in this method, the microloading phenomenon can be neglected and the depths of the recesses formed on the thermal oxide film can be uniformed.

However, the inventors have found that when the Ni stamper is formed by the method of Jpn. Pat. Appln. KOKAI Publication No. 2008-251095, microcracks are generated on the Ni stamper with a probability of about 50%. If such a Ni stamper in which microcracks are generated is used to manufacture a patterned medium, defects arise in the patterned medium, causing a reduction in recording density. Why the microcracks of the Ni stamper are generated is considered because a difference in expansion coefficient between the Ni electroforming layer and the Si substrate causes stress and the stress is relaxed due to some trigger. Under the circumstances, it is desired to develop a master plate for producing a Ni stamper capable of relaxing stress.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a plan view showing a discrete track medium (DTR medium);

FIG. 2 is a plan view showing a bit patterned medium (BPM);

FIGS. 3A, 3B, 3C and 3D are cross-sectional views showing a method of manufacturing a master plate according to an embodiment of the present invention;

FIGS. 4A, 4B and 4C are cross-sectional views showing a method of manufacturing a Ni stamper according to an embodiment of the present invention;

FIGS. 5A, 5B, 5C, 5D, 5E, 5F, 5G, 5H and 5I are cross-sectional views showing a method of manufacturing a pattered medium according to an embodiment of the present invention;

FIGS. 6A and 6B are cross-sectional views showing the resist residues left on the bottoms in recesses of a UV resist after imprinting; and

FIGS. 7A and 7B are perspective views conceptually showing LER of a master plate.

### DETAILED DESCRIPTION

Various embodiments according to the invention will be described hereinafter with reference to the accompanying drawings. In general, according to one embodiment of the invention, there is provided a master plate for producing a stamper, comprising: a substrate; and patterns of protrusions and recesses formed on the substrate and corresponding to patterns of recording tracks or recording bits in data areas and to information in servo areas, wherein the protrusion has a structure in which a first metal layer, a silicon (Si) layer and a second metal layer are stacked on the substrate and a metal oxide film is formed on a surface of the protrusion.

According to another embodiment of the invention, there is provided a method of manufacturing a master plate for producing a stamper, comprising: depositing a first metal layer, a silicon (Si) layer and a second metal layer on a substrate; applying an electron beam resist to the second metal layer; writing patterns corresponding to recording tracks or recording bits in data areas and patterns corresponding to information in servo areas by electron-beam lithography, followed by developing the resist to form patterns of protrusions and recesses; etching the second metal layer by using Ar gas; reactive ion etching the Si layer by using fluorine-containing gas; and exposing surfaces of the second metal layer, the Si layer and the first metal layer to oxygen plasma to form a metal oxide film.

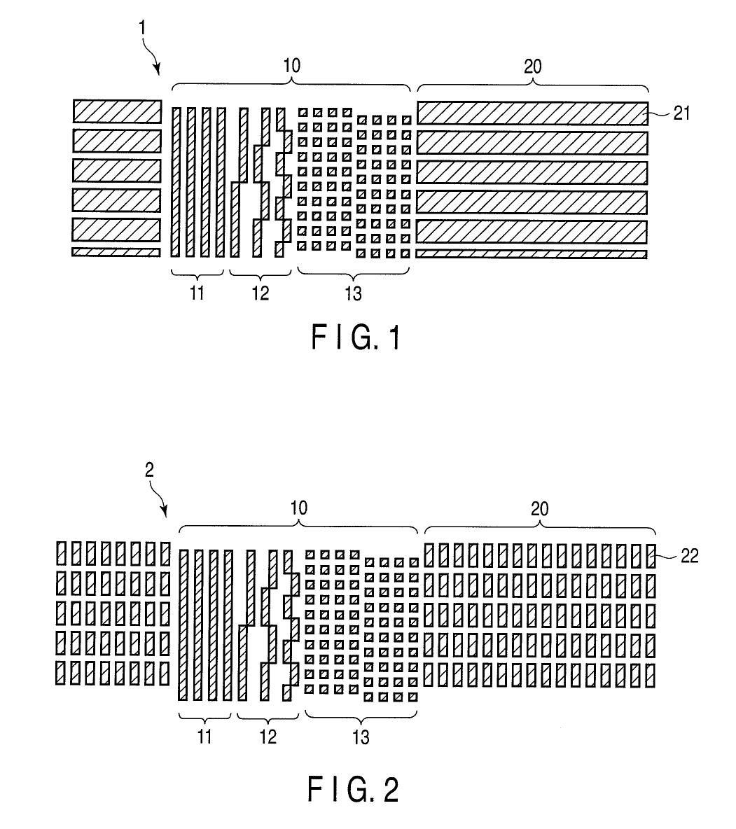

FIG. 1 shows a plan view of a DTR medium 1 along the circumferential direction. As shown in FIG. 1, servo areas 10 and data areas 20 are alternately formed along the circumferential direction of the medium 1. The serve area 10 includes a preamble section 11, an address section 12 and a burst section 13. The data area 20 includes discrete tracks 21 separated from each other.

FIG. 2 is a plan view of a BPM 2 along the circumferential direction. As shown in FIG. 2, the servo area 10 has a structure similar to that shown in FIG. 1. The data area 22 includes magnetic dots 22 separated from each other.

In embodiments of the present invention, a master plate or a Ni stamper is produced in which patterns corresponding to the recording tracks or recording bits in the data areas and patterns corresponding to the information in the servo areas of a DTR medium as shown in FIG. 1 or BPM as shown in FIG. 2 are formed in protrusions and recesses.

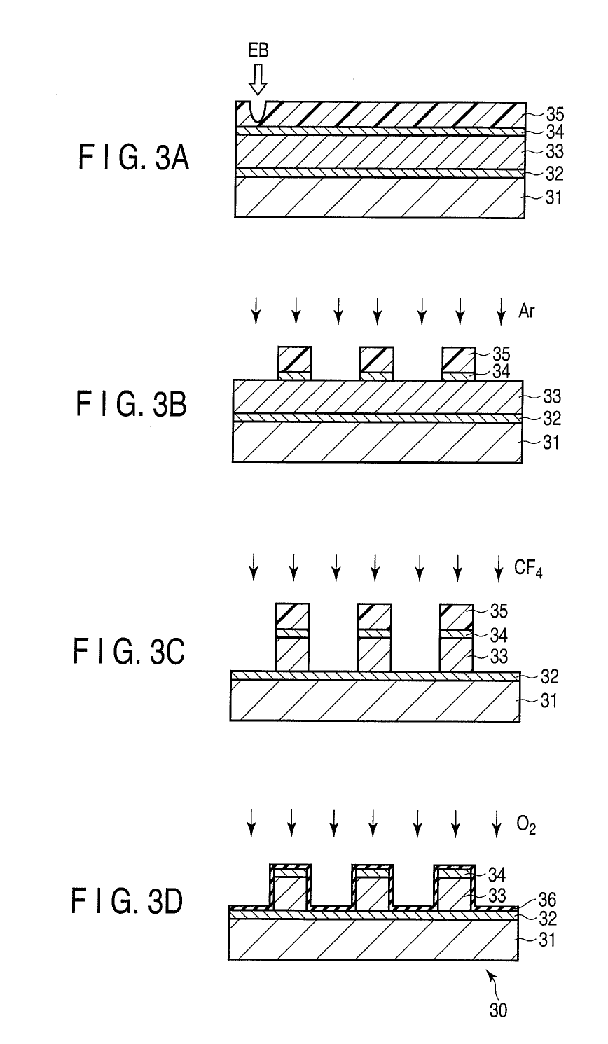

The method of manufacturing a master plate according to an embodiment of the present invention will now be described with reference to FIGS. 3A to 3D.

As shown in FIG. 3A, a 10-nm-thick first metal layer 32 made of Ni, a 40-nm-thick Si layer 33 and a 10-nm-thick second metal layer 34 made of Ni are deposited in this order on a 6-inch Si substrate 31 by sputtering. A solution prepared by two-fold diluting a resist, ZEP-520A manufactured by ZEON CORPORATION, with anisole and by filtering the diluted solution with a 0.05 μm filter is applied to the second metal layer 34 by spin coating, followed by prebaking at 200° C. for 3 minutes to form an EB resist 35 about 50 nm in thickness. Next, using an electron beam lithography system equipped with a ZrO/W thermal field emission type electron gun emitter, desired patterns are written directly on the EB resist 35 in a condition of an acceleration voltage of 50 kV. The writing is performed using a signal source that synchronously generates signals for forming servo patterns, burst patterns, address patterns and track patterns, signals fed to the stage driving system of the lithography system and control signals for electron beam deflection. The stage driving system is so-called X-θ stage driving system provided with a moving mechanism having a moving axis in at least one direction and a rotating mechanism. During writing, the stage is rotated at a constant linear velocity (CLV) of 500 mm/s and also moved in the radial direction. The electron beam is deflected every rotation to write the data areas forming concentric circles. Also, the electron beam is moved by 7.8 nm every rotation to form one track (corresponding to a width of one address bit) by 10 rotations. Then, the substrate is immersed in a developing solution (ZED-N50, manufactured by ZEON CORPORATION) for 90 seconds to develop the resist and then immersed in a rinsing solution (ZMD-B, manufactured by ZEON CORPORATION) for 90 seconds to rinse, followed by drying by air blowing. Thus, patterns of protrusions and recesses are formed on the EB resist.

As shown in FIG. 3B, the second metal layer (Ni) 34 having a thickness of 10 nm is etched by Ar ion beam etching using the patterns of EB resist 35 as masks. For example, an ECR (electron cyclotron resonance) ion gun is used to carry out etching for 5 seconds in the following conditions: microwave power of 800 W and an acceleration voltage of 1000 V. RIE improved in anisotropy may be substituted for the Ar ion beam etching.

As shown in FIG. 3C, the Si layer 33 is etched with an ICP (inductively coupled plasma) etching apparatus using process gas CF₄ in the following conditions: chamber pressure of 2 mTorr, coil RF power and platen RF power of 100 W and etching time of 30 seconds. The process gas can be freely selected from fluorine-containing gases and for example, CHF₃, C₂F₆ or SF₆ may be used.

As shown in FIG. 3D, the EB resist 35 is stripped off, and then the surfaces of the second metal layer 34, Si layer 33 and first metal layer 32 are exposed to oxygen plasma to form a metal oxide film 36. For example, RIE using oxygen gas is used to carry out treatment under the conditions of 100 mTorr, 100 W and 60 seconds. A master plate 30 in which the surfaces of the protrusions are made of the metal oxide film 36 is manufactured. The formation of the metal oxide film 36 on the surfaces of the protrusions ensures that the electroforming Ni stamper can be easily peeled off and also, occurrence of microcracks can be suppressed.

If the oxygen plasma exposure process is not carried out in accordance with an embodiment of the present invention and the Ni conductive film and the Ni electroforming layer are formed thereafter, the metal layer of the master plate and the Ni stamper are tightly adhered with each other which makes it impossible to peel them off from each other. Generally, a master plate is immersed in an organic solvent such as alcohols or acetone or alkalis such as a developing solution when the EB resist is peeled off. However, in this method, an oxidation process (passivation) cannot be performed on exposed portions of the protruded metal layer on the surface. Examples of the oxygen plasma exposure method include a method using a RIE system or ICP system and treatment using a UV radiation apparatus. The present invention defines that the protrusion has a structure in which the first metal layer, Si layer and second metal layer are stacked in this order from the substrate side and the metal oxide film is formed on the surface of the protrusion. This implies that it is only necessary that at least the outermost surface of the protrusion is a metal oxide film. However, oxidation may also be extended to the inside of the first metal layer, Si layer and second metal layer depending on the oxygen plasma exposure conditions. Thus, such a structure is also included in an embodiment of the present invention.

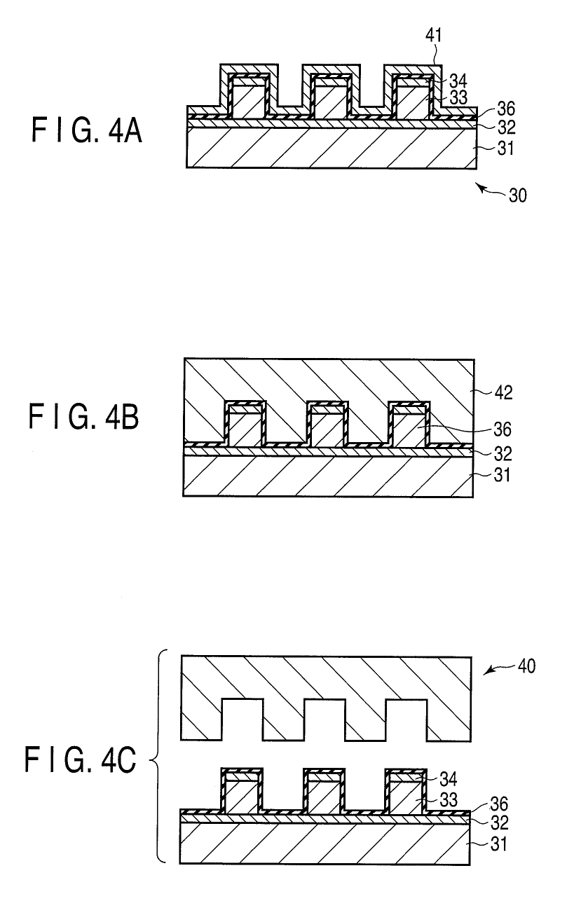

A method of manufacturing a Ni stamper will be described below with reference to FIGS. 4A to 4C.

As shown in FIG. 4A, on the master plate 30 of the present invention, a conductive film 41 made of Ni is formed by sputtering. For example, after the chamber is evacuated to 8×10⁻3 Pa, argon gas is introduced to adjust the pressure to 1 Pa. DC power of 400 W applied to carry out sputtering for 20 seconds to deposit a conductive film 41 made of about 5-nm-thick Ni. The conductive film 41 may be formed of an alloy obtained by blending a trace amount of V or Ru in Ni though it may be formed of pure Ni.

As shown in FIG. 4B, the master plate 30 on which the conductive film 41 is formed is immersed in, for example, a nickel sulfamate solution (NS-160, manufactured by Showa Chemical Industry Co., LTD.) to carry out Ni-electroforming for 90 minutes to form a Ni electroforming layer 42 about 300 μm in thickness. The conditions of the electroforming bath is as follows:

Nickel sulfamate: 600 g/L

Boric acid: 40 g/L

Surfactant (sodium laurylsulfate): 0.15 g/L

Solution temperature: 55° C.

pH: 4.0

Current density: 20 A/dm².

As shown in FIG. 4C, the Ni electroforming layer 42 and the conductive layer 41 are peeled off from the master plate 30 to produce a Ni stamper 40.

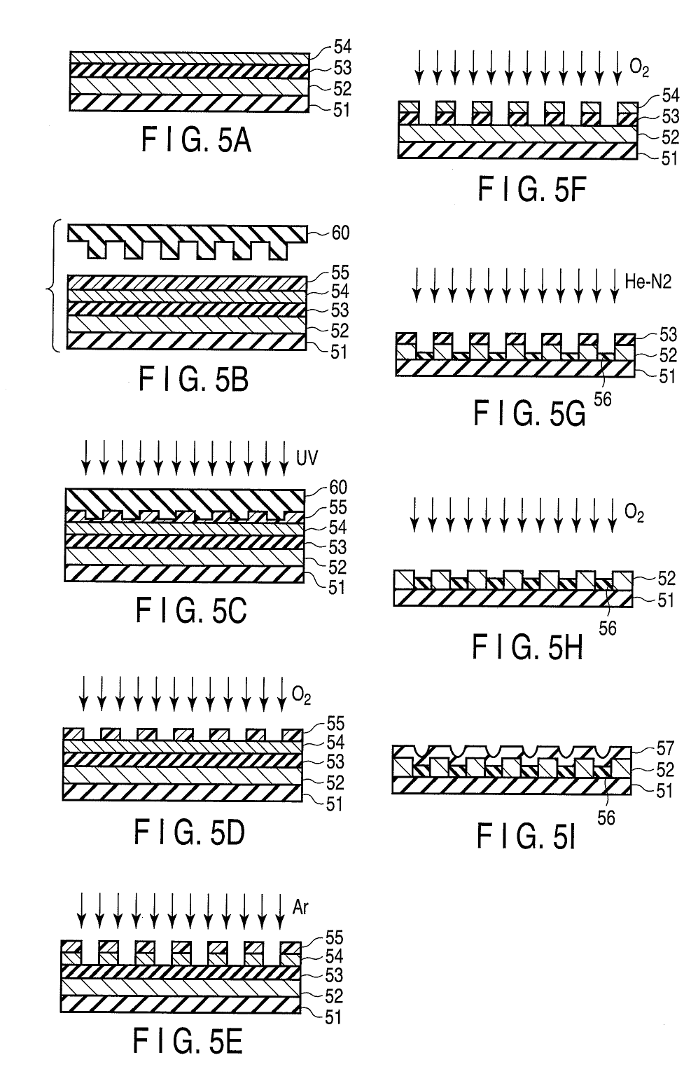

A method of manufacturing a magnetic recording medium (DTR medium or BPM) will be described below with reference to FIGS. 5A to 5I.

First, the Ni stamper 40 produced in the above manner is set to an injection molding machine (manufactured by TOSHIBA MACHINE CO., LTD.) to manufacture a resin stamper 60 by using the injection molding method. As the resin material, an olefin polymer (ZEONOR 1060R, manufactured by ZEON CORPORATION) or polycarbonate (AD5503, manufactured by Teijin Chemicals Ltd.) or the like may be used.

As shown in FIG. 5A, a 120-nm-thick soft magnetic underlayer (not shown) made of CoZrNb, a 20-nm-thick orientation control underlayer (not shown) made of Ru, a 15-nm-thick magnetic recording layer 52 made of CoCrPt—SiO₂, a 15-nm-thick etching protective layer 53 made of carbon and a 3 to 5-nm-thick metal layer 54 are formed in this order on a glass substrate 51. Here, the soft magnetic underlayer and the orientation control underlayer are not shown for the sake of simplicity.

As the metal layer 54, a metal is used which is highly adhesive to a UV-curable resist (photopolymer, 2P agent) which will be described later and is capable of stripping off at the time of etching using a mixed gas of He and N₂ which will be described later. Specific examples of the metal include CoPt, Cu, Al, NiTa, Ta, Ti, Si, Cr and NiNbZrTi. In particular, CoPt, Cu and Si are superior both in adhesion to the UV-curable resist and in stripping off by the mixed gas of He and N₂.

As shown in FIG. 5B, a UV-curable resist 55 is applied to the surface of the metal layer 54 in a thickness of 50 nm by spin coating. The UV-curable resist 55 contains a monomer, an oligomer and a polymerization initiator and exhibits ultraviolet-curable ability. For example, a composition containing 85% of isobornylacrylate (IBOA) as the monomer, 10% of a polyurethanediacrylate (PUDA) as the oligomer and 5% of Darocure 1173 as the polymerization initiator may be used. A resin stamper 60 is disposed so as to face the resist 54.

As shown in FIG. 5C, the resin stamper 60 is used to carry out imprinting to form protrusions of the UV resist 55 corresponding to the recesses of the resin stamper 60 and then, ultraviolet rays are applied to the UV-curable resist 55 through the resin stamper 60 to cure the UV-curable resist 55.

As shown in FIG. 5D, the resin stamper 60 is removed and then, the resist residues left on the bottoms in the recesses of the patterned UV-curable resist 55 are removed. For example, an ICP etching apparatus is used, oxygen is introduced as the process gas and other conditions are as follows: chamber pressure of 2 mTorr, coil RF power and platen RF power of 100 W and etching time of 30 seconds.

As shown in FIG. 5E, using the patterns of the UV-curable resist 55 as masks, the metal layer 54 is etched by ion beam etching using Ar gas. This process is not necessarily carried out. For example, when the resist residues are removed, the resist residues and the metal layer can be etched if highly anisotropic etching conditions are used. Specifically, the etching anisotropy can be improved when the platen RF power is raised to about 300 W in an ICP etching apparatus. When Si is used as the metal layer 54, CF₄ gas may be used to carry out etching.

As shown in FIG. 5F, the etching protective layer 53 is patterned using the patterns of the UV-curable resist 55 as masks. For example, an ICP etching apparatus is used, O₂ is introduced as the process gas and other conditions are as follows: chamber pressure of 2 mTorr, coil RF power and platen RF power of 100 W and etching time of 30 seconds.

As shown in FIG. 5G, ion beam etching using He or a mixed gas of He and N₂ (mixing ratio 1:1) is carried out by using the patterns of the etching protective layer 53 as masks to etch a part of the magnetic recording layer 52 to form protrusions and recesses and to deactivate the magnetic recording layer 52 left in the recesses, thereby forming a nonmagnetic layer 56. At this time, it is preferable to use ECR (electron cyclotron resonance) ion gas. The etching is carried out, for example, in the conditions of a microwave power of 800 W and an acceleration voltage of 1000 V for 20 seconds to form recesses 10 nm in depth on the magnetic recording layer 52 and to form a 5-nm-thick nonmagnetic layer 56 with the magnetism thereof deactivated. At the same time, the metal layer (for example, Si) 54 left unremoved is perfectly removed. This reason is that, in the next step, stripping-off of the etching protective layer (carbon) 53 cannot be attained by oxygen RIE in the state that the metal layer 54 is left unremoved.

As shown in FIG. 5H, the patterns of the etching protective layer (carbon) 53 are removed. For example, using oxygen gas, RIE etching is carried out under the conditions of 100 mTorr and 100 W for an etching time of 30 seconds.

As shown in FIG. 5I, a 4-nm-thick surface protective layer 57 made of carbon is deposited by CVD (chemical vapor deposition). A lubricant is applied to the surface of the surface protective film 57 to manufacture a DTR medium or BPM.

Here, differences between the present invention and the prior art will be summarized.

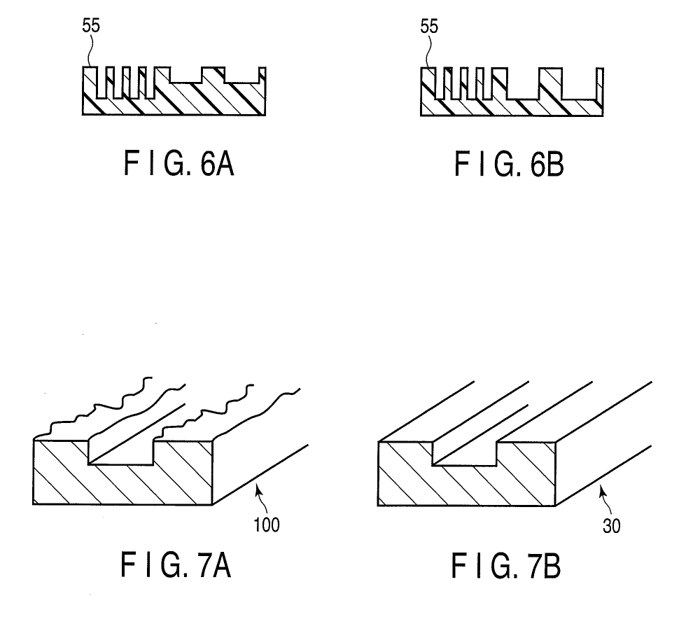

In a method of producing a master plate in the prior art, a microloading phenomenon is occurred in RIE process performed to etch Si substrate, causing dispersion in the depths of recesses between servo areas and data areas. Such dispersion is transferred from the master plate to the Ni stamper and hence to the resin stamper. If a resin stamper having dispersion in the recesses and protrusions is used to carry out UV imprinting as shown in FIG. 5C, this causes dispersion in the thicknesses of the resist residues left on the bottoms in recesses of the UV-curable resist as shown in FIG. 6A. This causes defective patterns in DTR medium or BPM to be manufactured.

In contrast, the master plate of the present invention has no dispersion in the depths of recesses between servo areas and data areas, and thus, the Ni stamper and resin stamper manufactured by sequential transfer from the master plate have less dispersion in protrusions and recesses. When a resin stamper having less dispersion in protrusions and recesses is used to carry out UV imprinting as shown in FIG. 5C, less dispersion is caused in the thicknesses of the resist residues left on the bottoms in recesses of the UV-curable resist 55. For this, DTR medium or BPM to be manufactured is free from defective patterns.

In the case where a Ni stamper is formed from a Si master plate by a conventional method, microcracks are generated on the Ni stamper, which limits the yield to be as small as about 50%. In the case of forming a Ni stamper from the master plate of the present invention, on the contrary, the yield can be increased to almost 100% because the occurrence of microcracks in the Ni stamper can be suppressed. This is considered because the protrusions in the master plate of the present invention has a structure in which the first metal layer, Si layer and second metal layer are stacked and the metal layer having ductility and malleability serves as a buffer layer to relax the stress in Ni electroforming.

It is found that a resin stamper manufactured from the master plate of the present invention and a DTR medium or BPM produced from the resin stamper is reduced in RRO (repeatable run-out) in contrast with conventional ones. The term RRO means strain synchronous to track position and indicates a deviation of a track from the perfect circle. It is considered that a Ni stamper produced by a conventional method is put into a state retaining the stress generated in electroforming and is therefore gradually strained, causing the strain of the molded resin stamper, which is a cause of RRO. It is considered, on the contrary, that a Ni stamper manufactured from the master plate of the present invention is reduced in internal stress and therefore, is resistant to strain during molding, with the result that the molded resin stamper has a small RRO.

It has been found that the master plate manufactured by the method of the present invention is improved in LER (line edge roughness). In a conventional method, crystalline Si is etched to manufacture a master plate. For this, as shown in FIG. 7A, LER dependent on the Si crystal grain size appears on the patterns of the Si master plate 100 and it is very difficult to reduce the LER to 8 nm or less. In the master plate of the present invention, on the contrary, the surface of the protrusions is made of an amorphous metal oxide film. For this, as shown in FIG. 7B, no LER dependent on the Si crystal grain size appears and it is therefore easy to reduce the LER to 8 nm or less. Because the LER affects SNR (signal-to-noise ratio), the reduction in the LER leads to improvement in the performance of a DTR medium or BPM.

It is found that the master plate of the present invention has an effect on the suppression of dusts. In a conventional method, the surface of the Si master plate is charged to collect particles in the air. In contrast, the master plate of the present invention does not collect particles in the air since the surface of the protrusions is made of a metal oxide film which is a dielectric.

The method of manufacturing a Ni stamper for injection molding from the master plate of the present invention is described above. However, applications of the master plate of the present invention are not limited thereto, and the master plate may also be used to manufacture a Ni stamper for nano imprinting.

The details of the materials and each process used in the present invention will be described.

(UV-Curable Resist)

The UV-Curable Resist (2P Agent) is a ultraviolet-curable material and is a composition which contains a monomer, an oligomer and a polymerization initiator and does not contain a solvent.

The following compounds are used as the monomer.

Acrylates:

Bisphenol A-ethylene oxide-modified diacrylate (BPEDA)

Dipentaerythritol hexa(penta)acrylate (DPEHA)

Dipentaerythritol monohydroxypentaacrylate (DPEHPA)

Dipropylene glycol diacrylate (DPGDA)

Ethoxylated trimethylolpropanetriacrylate (ETMPTA)

Glycerin propoxytriacrylate (GPTA)

4-Hydroxybutylacrylate (HBA)

1,6-Hexanediol diacrylate (HDDA)

2-Hydroxyethylacrylate (HEA)

2-Hydroxypropylacrylate (HPA)

Isobornylacrylate (IBOA)

Polyethylene glycol diacrylate (PEDA)

Pentaerythritol triacrylate (PETA)

Tetrahydrofurfurylacrylate (THFA)

Trimethylolpropanetriacrylate (TMPTA)

Tripropylene glycol diacrylate (TPGDA)

Methacrylates:

Tetraethylene glycol dimethacrylate (4EDMA)

Alkylmethacrylate (AKMA)

Arylmethacrylate (AMA)

1,3-butylene glycol dimethacrylate (BDMA)

n-Butylmethacrylate (BMA)

Benzylmethacrylate (BZMA)

Cyclohexylmethacrylate (CHMA)

Diethylene glycol dimethacrylate (DEGDMA)

2-Ethylhexylmethacrylate (EHMA)

Glycidylmethacrylate (GMA)

1,6-hexanedioldimethacrylate (HDDMA)

2-Hydroxyethylmethacrylate (2-HEMA)

Isobornylmethacrylate (IBMA)

Laurylmethacrylate (LMA)

Phenoxyethylmethacrylate (PEMA)

t-Butylmethacrylate (TBMA)

Tetrahydrofurfurylmethacrylate (THFMA)

Trimethylolpropanetrimethacrylate (TMPMA)

In particular, isobornylacrylate (IBOA), tripropylene glycol diacrylate (TPGDA), 1,6-hexanedioldiacrylate (HDDA), dipropylene glycol diacrylate (DPGDA), neopentyl glycol diacrylate (NPDA), ethoxyisocyanuric acid triacrylate (TITA) and the like are preferred because their viscosities can be reduced to 10 cP or less.

Oligomers include, for example, urethaneacrylate type materials such as polyurethanediacrylate (PUDA) and polyurethanehexaacrylate (PUHA), and, in addition, polymethylmethacrylate (PMMA), fluorinated polymethylmethacrylate (PMMA-F), polycarbonate diacrylate and fluorinated polycarbonate methylmethacrylate (PMMA-PC-F).

Polymerization initiators include Irugacure 184 and Darocure 1173 manufactured by Ciba-Geigy Corp.

(Removal of Residues)

The residues left on the bottoms in recesses of the resist are removed by RIE. As the plasma source, an ECR (electron cyclotron resonance) plasma system or general parallel plate type RIE system may be used, though ICP (inductively coupled plasma) which can produce high-density plasma under low pressure is desirable. It is preferable to use oxygen gas to remove the residues of the UV-curable resist (2P agent).

(Magnetism Deactivation Etching)

Though the depths of recesses are preferably designed to be 10 nm or less in consideration of the flying characteristics of the read/write head, it is necessary that the thickness of the magnetic recording layer be about 15 nm to secure the signal output. In light of this, if it is so designed that, in the magnetic recording layer with a thickness of 15 nm, a surface potion with a thickness of 10 nm is physically removed and the remainder portion with a thickness of 5 nm is deactivated in magnetism, the side erase and side read can be suppressed while the flying characteristics of the head is ensured and therefore, a DTR medium or BPM can be produced. As a method of deactivating the magnetism of the magnetic recording layer 5 nm in thickness, a method in which the recording layer is exposed to He or N₂ ions is used. When the recording layer is exposed to He ions, Hc (coercivity) is reduced with exposure time while retaining squareness of the hysteresis loop and the hysteresis disappears (magnetism deactivation). In this case, if the time taken to expose the recording layer to He gas is insufficient, a hysteresis having good squareness is retained, in other words, Hn (reversal nucleation field) is retained. However, this means that the magnetic layer on the bottoms in the recesses has recording ability, resulting in a loss of the advantage of a DTR medium or BPM. When the recording layer is exposed to N₂ ions, on the other hand, the squareness of the hysteresis loop is degraded with exposure time and the hysteresis disappears. In this case, Hc is scarcely decreased though Hn is sharply degraded. However, in this case, if the time taken to expose the recording layer to N₂ gas is insufficient, the magnetic layer having a high Hc is left on the bottoms in recesses, resulting in a loss of the advantage of a DTR medium or BPM. In light of this, the inventors have focused their attentions on a difference in the behavior of magnetism deactivation between He gas and N₂ gas and as a result, found that if a mixed gas of He and N₂ is used, the magnetism of the magnetic recording layer left on the bottoms in recesses can be efficiently deactivated while etching the magnetic recording layer.

(Stripping Off of the Etching Protective Film)

After the magnetism of the magnetic recording layer is deactivated, the etching protective film made of carbon is stripped off. The etching protective film can be easily stripped off by carrying out oxygen plasma treatment.

(Formation of a Protective Film and after-Treatment)

Finally, a surface protective film is formed. The surface protective film may be formed by sputtering or vacuum evaporation though it is preferably formed by CVD to improve the coverage on the protrusions and recesses. With the CVD method, a DLC film containing much sp³-bonded carbon can be formed. When the thickness of the surface protective film is less than 2 nm, this brings about poor coverage, whereas when the thickness exceeds 10 nm, the magnetic spacing between the head and the medium is increased, resulting in degraded SNR, and therefore, the thickness out of the above range is undesirable. A lubricant is applied to the surface of the surface protective film. The lubricants which may be used include, for example, perfluoropolyethers, fluorinated alcohols and fluorinated carboxylic acids.

### EXAMPLES

The present invention will be described in more detail by way of examples.

### Example 1

A master plate was manufactured by the method shown in FIGS. 3A to 3D. A 10-nm-thick first metal layer made of Ni, a 40-nm-thick Si and a 10-nm-thick second metal layer made of Ni were deposited in this order on a 6-inch Si substrate by sputtering. A 50-nm-thick EB resist was applied to the second metal layer. This Si substrate was set to an EB lithography system to write patterns corresponding to a DTR medium as shown in FIG. 1. The track pitch and the groove width were designed to be 75 nm and 25 nm, respectively. Using the patterns of the EB resist as masks, the second metal layer (Ni) was etched by an ECR ion gun using Ar gas. Then, the Si layer was etched with an ICP system using CF₄ gas. After the EB resist was stripped off, the surfaces of the second metal layer, Si layer and first metal layer were exposed to oxygen plasma for 60 seconds in an ICP system to form a metal oxide film on the surface of the protrusions, thereby manufacturing a master plate.

The protrusions and recesses of the resultant master plate were measured with AFM (atomic force microscope), to find that the depth of the recesses in each of the servo areas and data areas was 50 nm. The LER of a part corresponding to the track was measured, to find that it was 6 nm or less. When the surface of the master plate was visually observed by a light shading inspection using a Xe lamp, it was found that no particle adhered.

Next, a Ni stamper was manufactured from the produced master plate by the method shown in FIGS. 4A to 4C. A 5-nm-thick conductive film made of Ni was deposited on the master plate by sputtering. The substrate was immersed in a Ni sulfamate plating solution to carry out electroforming for 90 minutes, thereby forming a Ni electroforming layer. The Ni electroforming layer and the conductive film were peeled off to obtain a Ni stamper.

The resultant Ni stamper was set to an injection molding machine and a cyclic olefin polymer (ZEONOR 1060R, manufactured by ZEON CORPORATION) was used as a resin material to carry out injection molding under a condition of clamping force of 40 t, thereby manufacturing a resin stamper.

The manufactured resin stamper was subjected to an optical disk tester (DDU-1000, manufactured by Pulsetec Industrial Co., Ltd.) to evaluate RRO. As a result, it was found that the RRO variation was as small as 0.5 or less.

### Comparative Example 1

A Si master plate was manufactured by the method described in Jpn. Pat. Appln. KOKAI Publication No. 2008-251095. An EB resist 50 nm in thickness was applied to the surface of a 6-inch Si substrate. The Si substrate was set to an EB lithography system to write patterns corresponding to a DTR medium as shown in FIG. 1 in the same manner as in Example 1. Using the EB resist patterns as masks, the Si substrate was etched with an ICP system using CF₄ gas such that the depth of the recesses corresponding to the tracks was 50 nm. Using an ICP system, the EB resist was stripped off by oxygen plasma to obtain a Si master plate.

The protrusions and recesses of the obtained Si master plate was measured by AFM, to find that the depth of recesses in the servo areas was 45 nm and the depth of recesses in the data areas was 50 nm, exhibiting uneven protrusions and recesses. When the LER of the part corresponding to the track was measured, it was about 8 nm. When the surface of the Si master plate was visually observed by a light shading inspection using a Xe lamp, several particles were observed.

Next, a Ni stamper was manufactured from the produced Si master plate in the same manner as in Example 1. The resultant Ni stamper was set to an injection molding machine to manufacture a resin stamper in the same manner as in Example 1. The manufactured resin stamper was subjected to an optical disk tester to evaluate RRO. As a result, it was found that the RRO variation was 1.0 or less and the resin stamper had a larger RRO than the resin stamper of Example 1.

### Example 2

A master plate was manufactured in the same manner as in Example 1 except that Al, Cr, Co, Fe or Hf was used in place of Ni for the first and second metal layers to be formed on the 6-inch Si substrate. The protrusions and recesses of the obtained master plate were measured with AFM, to find that the depth of recesses in each of the servo areas and data areas was 50 nm. The LER of a part corresponding to the track was measured, to find that it was 6 nm or less in every master plate. When the surface of the master plate was visually observed by a light shading inspection using a Xe lamp, it was found that no particle adhered. A Ni stamper was manufactured from the produced master plate in the same manner as in Example 1. At this time, the Ni stamper could be peeled off from the master plate.

When Pt or the like which does not form an oxide as the metal formed on the 6-inch Si substrate, on the other hand, the master plate and the Ni stamper cannot be peeled off from each other in the production of the Ni stamper. Al, Cr, Co, Fe or Hf, on the other hand, easily forms an oxide and therefore, enables the production of a Ni stamper.

### Example 3

A master plate was manufactured in the same manner as in Example 1 except that the thickness of the Si layer was changed to those shown in Table 1. When the LER of the master plate was measured with SEM (scanning electron microscope), the results shown in Table 1 were obtained. When the thickness of the Si layer was 50 nm or less, the LER was 6 nm or less.

If the LER is not 10% or less of the track pitch, this is undesirable because the SNR of a DTR medium manufactured from this master plate is degraded. Since the track pitch is 75 nm in this example, the LER is preferably 7.5 nm or less from the viewpoint of SNR. Because, as listed in Table 1, the expression LER 7.5 nm is not satisfied unless the thickness of the Si layer is 50 nm or less, the thickness of the Si layer is preferably 50 nm or less to manufacture a DTR medium with a good SNR.

In accordance with the present invention, a Ni stamper is manufactured from the master plate and a resin stamper is manufactured from the Ni stamper, to finally manufacture a DTR medium. The depth of the recesses of the stamper is designed to be at least 5 nm to manufacture a DTR medium. The sum of the thickness of the second metal layer and the thickness of the Si layer corresponds to the depth of the groove of the stamper. Because the minimum thickness necessary for the second metal layer to be a flat thin film is 1 nm, the practical thickness of the Si layer is 4 nm or more. Accordingly, the thickness of the Si layer in the master plate is preferably 4 nm or more and 50 nm or less.

TABLE 1
Thickness of Si layer and LER

| Thickness of | LER |
|---|---|
| Si layer (nm) | (nm) |
| 5 | 4 |
| 10 | 5 |
| 25 | 5 |
| 50 | 6 |
| 75 | 8 |
| 100 | 10 |

### Example 4

A master plate was manufactured in the same manner as in Example 1 except that the thickness of the second metal layer (Ni) was changed to those shown in Table 2. Ten Ni stampers were continuously manufactured from the manufactured master plate by the method as shown in FIGS. 4A to 4C. The surface of the resultant Ni stamper was observed with an optical microscope to examine whether or not microcracks occur. The results are summarized in Table 2.

As shown in Table 2, it was found that when the thickness of the second metal layer is 30 nm or less, the defective rate (microcrack occurrence rate) was 10% or less. It was found that when the thickness of the second metal layer exceeded 30 nm, the defective rate was increased. If the defective rate exceeds 20%, this brings about cost-up in consideration of mass production and therefore, the thickness of the second metal layer is preferably 30 nm or less. Because the minimum thickness necessary for the second metal layer to be a flat thin film is 1 nm, the thickness of the second metal layer is preferably 1 nm or more and 30 nm or less.

TABLE 2
Thickness of second metal layer and microcrack occurrence rate

| Thickness of second | Microcrack | |
|---|---|---|
| metal layer (nm) | occurrence rate | |
| 5 | 0% | (0/10) |
| 10 | 0% | (0/10) |
| 20 | 0% | (0/10) |
| 30 | 10% | (1/10) |
| 40 | 20% | (2/10) |
| 50 | 40% | (4/10) |

### Example 5

A resin stamper was manufactured in the same manner as in Example 1. As the material for the resin stamper, ZEONOR 1060R, manufactured by ZEON CORPORATION, was used. Then, a DTR medium was manufactured by the method shown in FIGS. 5A to 5I. Si was used as the metal layer to be formed on the carbon protective layer for the magnetic recording layer. As the UV-curable resist, a composition containing 85% of IBOA, 10% of PUDA and 5% of Darocure 1173 was used. The manufactured DTR medium had the following specifications: track pitch of 75 nm, track width of 50 nm and groove width of 25 nm. After a lubricant was applied thereto, the DTR medium was installed in a HDD drive for evaluation. As a result, the positioning accuracy of the read/write head was 6 nm and the on-track BER (bit error rate) was 10⁻⁵.

### Example 6

A BPM was manufactured in the same method as in Example 5 except that the patterns shown in FIG. 2 were written in EB lithography of manufacturing the master plate. The bit size of the manufactured BPM was 55 nm×20 nm. In the case of BPM, BER could not be defined and therefore, the signal amplitude intensity was evaluated. The BPM was magnetized in one direction and installed in a drive to observe the readout waveform, with the result that the signal amplitude intensity was 200 mV. The positioning accuracy of the read/write head was 6 nm. It was found that a BPM could also be manufactured in the same method as in the case of a DTR medium.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A master plate for producing a stamper, comprising:
a substrate; and
patterns of protrusions and recesses on the substrate corresponding to recording tracks or recording bits in data areas and patterns of protrusions and recesses on the substrate and corresponding to information in servo areas,
wherein the protrusion comprises a structure in which a first metal layer, a silicon (Si) layer and a second metal layer are on the substrate and a metal oxide film is on a surface of the protrusion.

2. The master plate of claim 1, wherein the first and second metal layers comprise nickel (Ni).

3. The master plate of claim 1, wherein the first and second metal layers comprise a metal selected from the group consisting of aluminum (Al), chromium (Cr), cobalt (Co), iron (Fe), and hafnium (Hf).

4. The master plate of claim 1, wherein the Si layer is 50 nm or thinner.

5. The master plate of claim 1, wherein the second metal layer is 30 nm or thinner.

6. A method of manufacturing a master plate for producing a stamper, comprising:
depositing a first metal layer, a silicon (Si) layer and a second metal layer on a substrate;
applying an electron beam resist to the second metal layer;
writing patterns corresponding to recording tracks or recording bits in data areas and patterns corresponding to information in servo areas by electron-beam lithography, followed by developing the resist to form patterns of protrusions and recesses;
etching the second metal layer by using argon (Ar) gas;
reactive ion etching the Si layer with fluorine-containing gas; and
exposing surfaces of the second metal layer, the Si layer and the first metal layer to oxygen plasma to form a metal oxide film.

7. A method of manufacturing a nickel stamper, comprising:
forming a conductive film on the master plate for producing a stamper comprising:
a substrate; and
patterns of protrusions and recesses on the substrate corresponding to recording tracks or recording bits in data areas and patterns of protrusions and recesses on the substrate and corresponding to information in servo areas,
wherein the protrusion comprises a structure in which a first metal layer, a silicon (Si) layer and a second metal layer are on the substrate and a metal oxide film is on a surface of the protrusion;
forming a nickel (Ni) electroforming layer on the conductive film; and
peeling off the Ni electroforming layer from the master plate.
